(19) United States
(12) Patent Application Publication
(10) Pub. No.: US 2025/0366305 A1
(43) Pub. Date: Nov. 27, 2025

(54) LIGHT-EMITTING DEVICE AND PREPARATION METHOD THEREOF, AND DISPLAY DEVICE

(71) Applicant: Shenzhen TCL High-Tech Development Co., Ltd., Shenzhen (CN)

(72) Inventor: Wenjun HOU, Shenzhen (CN)

(73) Assignee: Shenzhen TCL High-Tech Development Co., Ltd., Shenzhen (CN)

(21) Appl. No.: 19/211,123

(22) Filed: May 16, 2025

(30) Foreign Application Priority Data
May 22, 2024 (CN) 202410646159.4

(51) Int. Cl. H10K 50/15; H10K 50/115; H10K 71/12

(52) U.S. Cl. CPC H10K 50/156; H10K 50/115; H10K 71/12

(57) ABSTRACT

Disclosed in the present disclosure are a light-emitting device and a preparation method thereof, and a display device. The light-emitting device including a first electrode, a second electrode disposed opposite the first electrode, n light-emitting layers disposed between the first electrode and the second electrode, and m connecting layers disposed between the first electrode and the second electrode, where n and m are positive integers; at least one of the connecting layers includes an N-type layer, the N-type layer including a plurality of N-type sublayers, with a material of each of the N-type sublayers independently including an N-type metal oxide.

This application claims priority to Chinese Application No. 202410646159.4, entitled “LIGHT-EMITTING DEVICE AND PREPARATION METHOD THEREOF, AND DISPLAY DEVICE”, filed on May 22, 2024. The entire disclosures of the above application are incorporated herein by reference.

### TECHNICAL FIELD

The present disclosure relates to a technical field of semiconductor devices, and more particularly, to a light-emitting device and a preparation method thereof, and a display device.

### BACKGROUND

Light-emitting devices emit light through the recombination of electrons and holes, and are widely used in lighting, display, communication, intelligence and other fields. With the continuous development and transformation of various fields, the demand for light-emitting devices is also growing, and more differentiated and diversified light-emitting devices are needed.

### TECHNICAL SOLUTION

In view of this, the present disclosure provides a light-emitting device and a preparation method thereof, and a display device.

Embodiments of the present disclosure is realized as follows.

In a first aspect, the present disclosure provides a light-emitting device including a first electrode, a second electrode disposed opposite the first electrode, n light-emitting layers disposed between the first electrode and the second electrode, and m connecting layers disposed between the first electrode and the second electrode, where n and m are positive integers;
at least one of the connecting layers includes an N-type layer, the N-type layer including a plurality of N-type sublayers, with a material of each of the N-type sublayers independently including an N-type metal oxide.

In a second aspect, the present disclosure provides a method of preparing a ight-emitting device, including:
providing a first electrode;
providing a light-emitting functional layer on a side of the first electrode, wherein the light-emitting functional layer includes n light-emitting layers and m connecting layers, where n and m are positive integers; and,
providing a second electrode on a side of the light-emitting functional layer facing away from the first electrode to obtain a light-emitting device;
wherein the first electrode is selected from one of an anode and a cathode, and the second electrode is selected from the other of the anode and the cathode;
the process of preparing the N-type layer includes providing a plurality of solutions, each containing an N-type metal oxide, and sequentially depositing a plurality of the solutions to obtain a plurality of N-type sublayers.

In a third aspect, the present disclosure provides a display device including the light-emitting device described above, or including a light-emitting device prepared by the method described above.

### BRIEF DESCRIPTION OF DRAWINGS

In order to more clearly explain the technical solutions in the embodiments of the present disclosure, the drawings to be used in the description of the embodiments are briefly described below. It is apparent that the drawings in the following description are merely some embodiments of the present disclosure. For those skilled in the art, without involving any creative effort, other drawings may be obtained based on these drawings.

FIG. 1 is a schematic structural diagram of a first embodiment of a light emitting device provided by the present disclosure.

FIG. 2 is a schematic structural diagram of a second embodiment of a light emitting device provided by the present disclosure.

FIG. 3 is a schematic structural diagram of a third embodiment of a light emitting device provided by the present disclosure.

FIG. 4 is a schematic structural diagram of a fourth embodiment of a light emitting device provided by the present disclosure.

FIG. 5 is a schematic structural diagram of a fifth embodiment of a light emitting device provided by the present disclosure.

FIG. 6 is a schematic structural diagram of a sixth embodiment of a light emitting device provided by the present disclosure.

FIG. 7 is a flow chart of a method of preparing a light emitting device according to an embodiment of the present disclosure.

FIG. 8 is a flow chart of a method of preparing a light emitting device according to another embodiment of the present disclosure.

### DETAILED DESCRIPTION

Technical solutions in embodiments of the present disclosure will be clearly and completely described below with reference to the figures in the embodiments of the present disclosure. It is apparent that, the described embodiments are only a part of embodiments of the present disclosure, rather than all the embodiments. Based on the embodiments in the present disclosure, all other embodiments obtained by those skilled in the art without creative effort fall within the protection scope of the present disclosure. Furthermore, it should be understood that the detailed description described herein is for illustration and explanation of the present disclosure only, and is not intended to limit the present disclosure. In the present disclosure, unless otherwise stated, location words such as “upper” and “lower” are used to specifically refer to the plane direction in the drawings. Additionally, in the description of the present disclosure, the term “including” means “including but not limited to”. Various embodiments of the present disclosure may exist in a range of forms. It should be understood that the description in a range form is for convenience and brevity only, and should not be construed as a hard limitation on the scope of the present disclosure. Accordingly, it should be considered that the stated range description has specifically disclosed all possible sub-ranges as well as single numerical values within the range. For example, it should be considered that a range from 1 to 6 has specifically disclosed subranges, such as from 1 to 3, from 1 to 4, from 1 to 5, from 2 to 4, from 2 to 6, from 3 to 6, and the like, and single numbers within the range, such as 1, 2, 3, 4, 5, and 6, which apply regardless of the range. In addition, whenever a numerical range is indicated herein, it is meant to include any referenced number (fraction or integer) within the indicated range.

In the present disclosure, “and/or” describes the association relationship of the association object, and indicates that there may be three kinds of relationships, for example, A and/or B, which may indicate that A exists alone, A and B exist at the same time, and B exists alone. A and B may be singular or plural.

In the present disclosure, “at least one” refers to one or more, and “a plurality” refers to two or more. “at least one of the following”, or similar expressions thereof refer to any combination of these items, including any combination of single or plural items. For example, “at least one of a, b, or c”, or “at least one of a, b, and c” may all mean: a, b, c, a-b (that is, a and b), a-c, b-c, or a-b-c, wherein a, b, and c, may be a single item or a plurality of items, respectively.

In a first aspect, the present disclosure provides a light-emitting device 100, such as an organic light-emitting diode (OLED), a quantum dot light-emitting diode (QLED), etc. The technical solution of the present disclosure provides a new light-emitting device 100, expanding the types of light-emitting devices 100 to meet the differentiated and diversified needs for light-emitting devices 100 in industrial applications.

Referring to FIG. 1, the light-emitting device 100 includes a first electrode, a second electrode disposed opposite the first electrode, n light-emitting layers disposed between the first electrode and the second electrode, and m connecting layers 40 disposed between the first electrode and the second electrode, where n and m are positive integers.

It can be understood that the light-emitting device 100 may be an upright device or an inverted device, correspondingly, the first electrode may be selected from one of the anode 10 and the cathode 20, and the second electrode may be selected from the other of the anode 10 and the cathode 20. Specifically, when the light-emitting device 100 is the upright device, the first electrode is the anode 10 and the second electrode is the cathode 20, and when the light-emitting device 100 is the inverted device, the first electrode is the cathode 20 and the second electrode is the anode 10.

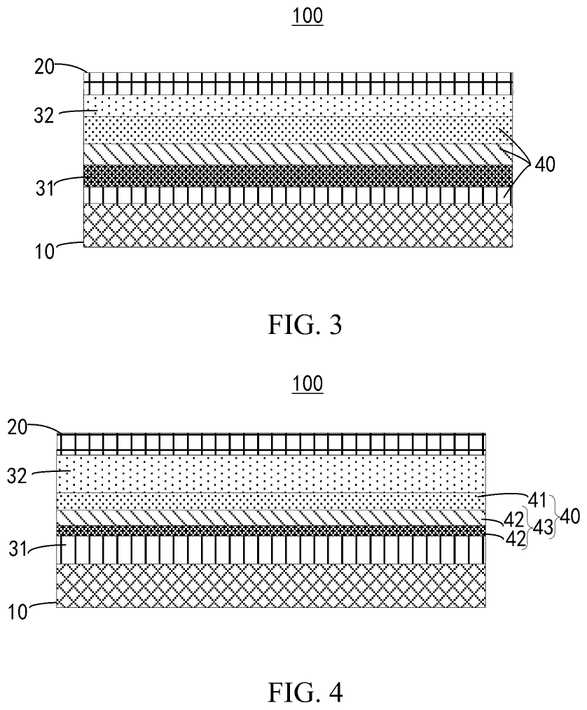

Referring to FIG. 3, the connecting layer 40 includes one or more of a P-type layer 41 and an N-type layer 43. For example, the connecting layer 40 may be composed of the P-type layer 41, may be composed of the N-type layer 43, or may include both the N-type layer 43 and the P-type layer 41. When both the N-type layer 43 and the P-type layer 41 are present, the N-type layer 43 in the connecting layer 40 is disposed close to the anode 10 and the P-type layer 41 is disposed close to the cathode 20 regardless of how the first electrode and the second electrode are disposed. For example, in some embodiments, when the first electrode is the anode 10 and the second electrode is the cathode 20, the N-type layer 43 and the P-type layer 41 are sequentially stacked in a direction from the first electrode to the second electrode. A film layer structure of each of the m connecting layers 40 may be set and adjusted according to the light emission requirements of the light emitting device 100, and they may be the same or different. For example, among the m connecting layers 40, at least one connecting layer 40 is composed of the N-type layer 43, and at least one connecting layer 40 contains both the N-type layer 43 and the P-type layer 41.

In some embodiments, among the m connecting layers 40, there is at least one connecting layer 40 including the N-type layer 43, and the N-type layer 43 includes a plurality of N-type sublayers 42, each of which independently includes an N-type metal oxide.

The specific position of the connecting layer 40 may be selected in various ways, and for example, it may be disposed between two adjacent light-emitting layers, between the first electrode and the light-emitting layer, or between the second electrode and the light-emitting layer.

Referring to FIG. 1, in some embodiments, at least one of the connecting layers 40 may be disposed between two adjacent of the light-emitting layers. Specifically, among the n light-emitting layers of the light-emitting device 100, two light-emitting layers may be adjacent to each other, and one, two, or more connecting layers 40 may be disposed between the two light-emitting layers. It is to be understood that among the n light-emitting layers of the light-emitting device 100, at least one group of adjacent light-emitting layers may not be provided with the connecting layer 40.

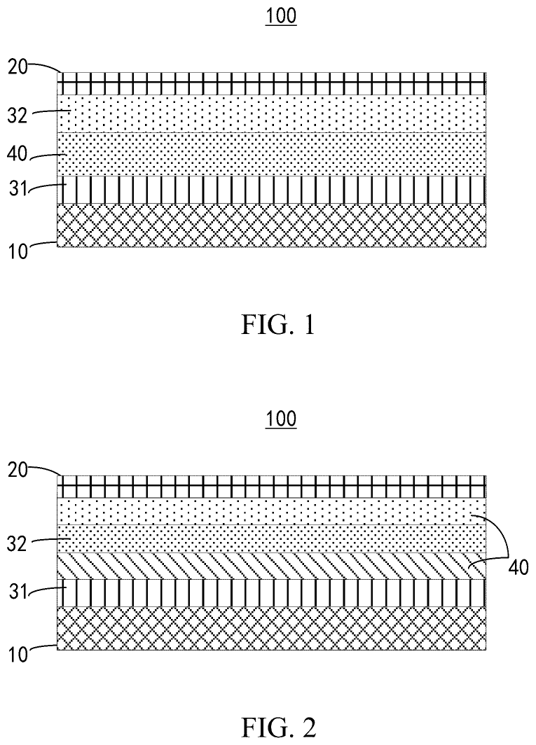

Referring to FIG. 2, in some embodiments, at least one of the connecting layers 40 may be disposed between the first electrode and one of the light-emitting layers closest to the first electrode. Referring to FIG. 3, in other embodiments, at least one of the connecting layers 40 may be further disposed between the second electrode and one of the light-emitting layers closest to the second electrode.

In some embodiments, in the light-emitting device 100, the connecting layer 40 is disposed between two adjacent light-emitting layers, and one connecting layer 40 is disposed between any two adjacent light-emitting layers.

In some embodiments, the connecting layer 40 further includes the P-type layer 41 stacked on a side of the plurality of N-type sublayers, that is, the connecting layer 40 includes both the N-type layer 43 and the P-type layer 41. The N-type layer 43 and the P-type layer 41 may constitute a charge-generationlayer, and when they are between two adjacent light-emitting layers, a hole-electron pair may be generated, and a plurality of light-emitting layers are connected in series, so that carriers do not need to cross the energy level barrier from an electrode to a charge injection layer, so that the device has doubled current efficiency, luminous brightness, and service life.

However, the increase in the number of film layers also leads to an increase in the driving voltage of the device. In view of this, in some embodiments, in the N-type layer 43, an average particle size of the N-type metal oxide contained in the N-type sublayer 42 closest to the cathode 20 is larger than that in the N-type sublayer 42 farthest from the cathode 20. Among the plurality of N-type sublayers 42, the average particle size of the N-type metal oxide contained in the N-type sublayer 42 closest to the P-type layer 41 is larger than that in the N-type sublayer 42 farthest from the P-type layer 41. The average particle size may be measured by using a Dynamic Light Scattering (DLS) method or using a Transmission Electron Microscope (TEM).

In some embodiments, in the N-type layer 43, a band gap width of the N-type metal oxide contained in the N-type sublayer 42 closest to the cathode 20 is smaller than a band gap width of the N-type metal oxide contained in the N-type sublayer 42 farthest from the cathode 20. That is, among the plurality of N-type sublayers 42, a band gap width of the N-type metal oxide contained in the N-type sublayer 42 closest to the P-type layer 41 is smaller than a band gap width of the N-type metal oxide contained in the N-type sublayer 42 farthest from the P-type layer 41. The energy level information of a material may be obtained by using X-ray photoelectron spectroscopy (XPS, also known as ESCA, Electron Spectroscopy for Chemical Analysis) and ultraviolet photo-electron spectroscopy (UPS, ultraviolet photo-electron spectroscopy) to detect the energy level of the material, and obtain its band gap width. Specifically, in UPS, the energy difference of the valence band top relative to the Fermi level can be directly obtained by measuring the kinetic energy of ultraviolet photoelectrons emitted from the surface of the material. Then, combined with the Fermi level positions measured by XPS, the band gap of the quantum dots can be estimated.

For convenience of description, the N-type sublayer 42 closest to the P-type layer 41 is defined as a top N-type sublayer, and the N-type sublayer 42 farthest from the P-type layer 41 is defined as a bottom N-type sublayer. The N-type metal oxide contained in the top N-type sublayer has a relatively large particle size, thus having a narrow band gap width and high electron mobility, and thus the energy level of the top N-type sublayer is closer to the HOMO energy level of the P-type layer 41, thereby contributing to the improvement of the charge generation efficiency of the connecting layer 40, thereby improving the electron mobility.

In some embodiments, the average particle size of the N-type metal oxide contained in the N-type sublayer 42 gradually decreases in a direction away from the P-type layer 41. In other embodiments, the band gap width of the N-type metal oxide contained in the N-type sublayer 42 gradually increases away from the P-type layer 41. It can be understood that the direction away from the P-type layer 41 is also a direction from the cathode 20 to the anode 10. In the N-type layer 43, in the direction away from the P-type layer 41, the average particle size of the metal oxide changes in a decreasing tendency, and the band gap width changes in a increasing tendency, which is beneficial to promote charge generation and separation, greatly improve the stability and current efficiency of the light-emitting device 100, and reduce the operating voltage thereof.

In some embodiments, among the plurality of N-type sublayers 42, a thickness of the N-type sublayer 42 closest to the P-type layer 41 (or closest to the cathode 20) is greater than or equal to a thickness of the N-type sublayer 42 farthest from the P-type layer 41 (or closest to the cathode 20). The N-type sublayer 42 close to the P-type layer 41 is made of a metal oxide having a large particle size and a low band gap width, so that the N-type sublayer 42 close to the P-type layer 41 has a high electron mobility, and at the same time, the thickness of the N-type sublayer 42 close to the P-type layer 41 is increased, which helps to improve the charge transport efficiency.

A thickness of the N-type layer 43 ranges from 30 nm to 50 nm. For example, it may be 30 nm, 35 nm, 40 nm, 45 nm, 50 nm, or a value between any two of the above values.

The thickness of the N-type sublayer 42 ranges from 10 nm to 40 nm. For example, it may be 10 nm, 15 nm, 20 nm, 25 nm, 30 nm, 35 nm, 40 nm, or a value between any two of the above values.

A thickness of the P-type layer 41 ranges from 10 nm to 30 nm. For example, it may be 10 nm, 15 nm, 20 nm, 25 nm, 30 nm, or a value between any two of the above values.

The N-type metal oxide may be any N-type metal oxide commonly used in the art, and may include, but are not limited to, one or more of an undoped metal oxide and a doped metal oxide. The undoped metal oxides may include, but are not limited to, one or more of ZnO, TiO₂, and SnO₂. The metal oxide in the doped metal oxide may include, but is not limited to, one or more of ZnO, TiO₂, and SnO₂, and doping elements in the doped metal oxide includes one or more of Al, Mg, Li, In, and Ga.

The average particle size of the N-type metal oxide ranges from 1 nm to 20 nm. For example, it may be 1 nm, 2 nm, 3 nm, 4 nm, 5 nm, 7 nm, 8 nm, 10 nm, 12 nm, 14 nm, 15 nm, 18 nm, 19 nm, 20 nm, or a value between any two of the above values. By selecting a metal oxide having a particle size within the above particle size range to prepare the N-type layer 43, better electrical properties and film-forming effect may be obtained.

In some embodiments, the number of the light-emitting layers is 2 to 4. For example, it may be 2, 3, or 4. Correspondingly, in other embodiments, the number of the connecting layers 40 is 1 to 3. For example, it may be 1, 2, or 3. Controlling the number of light-emitting layers within this range helps to balance the improvement of performance and the size of working voltage, and helps to improve the practicality of the device.

In some embodiments, in the N-type layer 43, the number of N-type sublayers 42 is 1 to 3. For example, the number of N-type sublayers 42 may be 1, 2, or 3. Controlling the number of N-type sublayers 42 within this range helps to improve device stability and photoelectric performance while taking into account device manufacturing difficulty and driving energy consumption.

In the light-emitting device 100 provided by some specific embodiments, the number of light-emitting layers is two, the number of connecting layers 40 is one, and two N-type sublayers 42 are provided in the N-type layer 43, so that the light-emitting device 100 designed in this way has lower driving voltage, better electrical properties, and is easy to process. Specifically, in the present embodiment, when the plurality of light-emitting layers include a first light-emitting layer 31 and a second light-emitting layer 32, and the N-type layer 43 includes a first N-type sublayer and a second N-type sublayer, the light-emitting device 100 includes the first electrode, the first light-emitting layer 31, the connecting layer 40, the second light-emitting layer 32, and the second electrode that are stacked in this order, and the connecting layer 40 includes the first N-type sublayer, the second N-type sublayer, and the P-type layer 41 that are stacked in this order in the direction of the first electrode toward the second electrode. The second N-type sublayer contains an N-type metal oxide having a larger average particle size and a lower band gap width than the first N-type sublayer.

In another specific embodiment, the number of light-emitting layers is three, the number of connecting layers 40 is two, and two N-type sublayers 42 are provided in the N-type layer 43 of each connecting layer 40. Specifically, as shown in FIG. 6, in the present embodiment, the plurality of light-emitting layers include the first light-emitting layer 31, the second light-emitting layer 32, and a third light-emitting layer 33, the plurality of connecting layers 40 include a first connecting layer 40a and a second connecting layer 40b, and in each connecting layer 40, the N-type layer 43 includes the first N-type sublayer and the second N-type sublayer. Accordingly, the light-emitting device 100 includes the first electrode, the first light-emitting layer 31, the first connecting layer 40a, the second light-emitting layer 32, the second connecting layer 40b, the third light-emitting layer 33, and the second electrode that are stacked in this order, and the first connecting layer 40a and the second connecting layer 40b independently include the first N-type sublayer, the second N-type sublayer, and the P-type layer 41 that are stacked in this order along the direction of the first electrode toward the second electrode. The second N-type sublayer contains an N-type metal oxide having a larger average particle size and a lower band gap width than the first N-type sublayer.

A material of the first N-type sublayer and a material of the second N-type sublayer are each independently selected from one or more of doped zinc oxide nanoparticles, undoped zinc oxide nanoparticles, doped tin oxide nanoparticles and undoped tin oxide nanoparticles, such as Zn_{0.9}Mg_{0.10}, ZnO, Zn_{0.85}Mg_{0.15}O, Zn_{0.95}Mg_{0.05}O, SnO₂, and the like.

In some embodiments, the material of the first N-type sublayer has an average particle size of 2 nm to 5 nm. For example, it may be 2 nm, 3 nm, 4 nm, 5 nm, or a value between any two of the above values. A band gap width of the material of the first N-type sublayer ranges from 3.6 ev to 4.2 ev. For example, it may be 3.6 ev, 3.7 ev, 3.8 ev, 3.9 ev, 4 ev, 4.1 ev, 4.2 ev, or a value between any two of the above values. A thickness of the first N-type sublayer is 10 nm to 20 nm. For example, it may be 10 nm, 11 nm, 12 nm, 13 nm, 14 nm, 15 nm, 16 nm, 17 nm, 18 nm, 19 nm, 20 nm, or a value between any two of the above values.

In other embodiments, the material of the second N-type sublayer has an average particle size of 5 nm to 8 nm. For example, it may be 5 nm, 6 nm, 7 nm, 8 nm, or a value between any two of the above values. The material of the second N-type sublayer has a band gap width of 3.2 ev to 3.6 ev. For example, it may be 3.2 ev, 3.3 ev, 3.4 ev, 3.5 ev, 3.6 ev, or a value between any two of the above values. A thickness of the second N-type sublayer is 20-40 nm. For example, it may be 20 nm, 25 nm, 30 nm, 35 nm, 40 nm, or a value between any two of the above values.

A material of the P-type layer 41 may employ a P-type layer 41 semiconductor material commonly used in the art, and may include, for example, but not limited to, at least one of polythiophene, polyaniline, 2,3,6,7,10,11-hexacyano-1,4,5,8,9,12-hexaazabenzophenanthrene, PEDOT, PEDOT:PSS, a derivative of PEDOT:PSS doped with s-MoO₃, 4,4′,4′-tris(N-3-methylphenyl-N-phenylamino) triphenylamine, tetracyanoquinone dimethane, copper phthalocyanine, nickel oxide (NiO), molybdenum oxide (MoO₃), tungsten oxide (WO₃), vanadium oxide (V₂O₅), molybdenum sulfide (MoS₃), tungsten sulfide (WS₃) and copper oxide (CuO).

It is understood that when the device includes a plurality of connecting layers 40, the materials of the P-type layers 41 of the plurality of connecting layers 40 may be the same or different, and the thicknesses of the P-type layers 41 of the plurality of connecting layers 40 may be the same or different. Similarly, the material and thickness of the N-type sublayer 42 of each connecting layer 40 may be independently selected, and the material and thickness thereof may be the same as or different from the N-type sublayer 42 in the other connecting layers 40.

The first electrode and the second electrode are each independently selected from one of a metal electrode, a carbon electrode, a doped or undoped metal oxide electrode, and a composite electrode. A material of the metal electrode is selected from at least one of Al, Ag, Cu, Mo, Au, Ba, Ca, Ni, Ir, and Mg. A material of the carbon electrode is selected from at least one of graphite, carbon nanotubes, graphene, and carbon fibers. A material of the doped or undoped metal oxide electrode is selected from at least one of ITO, FTO, ATO, AZO, GZO, IZO, MZO, ITZO, ICO, AMO, SnO₂, In₂O₃, Cd:ZnO, and Ga:SnO₂. A material of the composite electrode is selected from one of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS and ZnS/Al/ZnS. In this context, “/” represents a laminated structure, and for example, the composite electrode AZO/Ag/AZO represents an electrode having a composite structure in which three layers consisting of an AZO layer, an Ag layer, and an AZO layer are stacked.

Each time the light-emitting layer appears, a material of the light-emitting layer is independently selected from quantum dot light-emitting materials; the quantum dot light-emitting materials are selected from at least one of the group consisting of a single structure quantum dot, a core-shell structure quantum dot, and a perovskite type semiconductor material, the core-shell structure quantum dot has one or more shell layers; a material of the single structure quantum dot is selected from at least one of a Group II-VI compound, a Group IV-VI compound, a Group III-V compound, and a Group I-III-VI compound; the Group II-VI compound is selected from at least one of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe; the Group IV-VI compound is selected from at least one of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe; the Group III-V compound is selected from at least one of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb; the Group I-III-VI compound is selected from one or more of CuInS, CuInSe, and AgInS; a core of the core-shell structure quantum dot is selected from any one of the single structure quantum dots, and a shell material of the core-shell structure quantum dot is selected from at least one of CdS, CdTe, CdSeTe, CdZnSe, CdZnS, CdSeS, ZnSe, ZnSeS, and ZnS. As an example, the quantum dots of the core-shell structure may be selected from, but not limited to, at least one of CdZnSe/CdZnSe/ZnSe/CdZnS/ZnS, CdZnSe/CdZnSe/CdZnS/ZnS CdSe/CdSeS/CdS, InP/ZnSeS/ZnS, CdZnSe/ZnSe/ZnS, CdSeS/ZnSeS/ZnS, CdSe/ZnSe/ZnS, CdSe/CdZnSeS/ZnS, and InP/ZnSe/ZnS. For the material of the single structure quantum dot, a core material of the core-shell structure quantum dot, or a shell material of the core-shell structure quantum dot, the chemical formula provided only indicates the elemental composition and does not indicate the content of each element. For example, CdZnSe only indicates that a material is composed of three elements: Cd, Zn and Se. If it indicates the content of each element, it corresponds to CdₓZn₁₋ₓSe, 0<x<1.

The perovskite type semiconductor is selected from one of a doped inorganic perovskite type semiconductor, an undoped inorganic perovskite type semiconductor, and an organic-inorganic hybrid perovskite type semiconductor, a general structure formula of the inorganic perovskite type semiconductor is AMX₃, wherein A is Cs⁺, M is a divalent metal cation selected from one of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, X is a halogen anion selected from one of Cl⁻, Br⁻, and I⁻; a general structure formula of the organic-inorganic hybrid perovskite type semiconductor is BMX₃, wherein B is an organic amine cation selected from CH₃(CH₂)ₙ₋₂NH₃⁺ (n≥2) or NH₃(CH₂)ₙNH₃²⁺ (n≥2), M is a divalent metal cation selected from one of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, X is a halogen anion selected from one of Cl⁻, Br⁻, and I⁻.

It is to be understood that the materials of the plurality of light-emitting layers may be the same or different.

In some embodiments, a thickness of the light-emitting layer ranges from 10 nm to 50 nm. It is to be understood that the thicknesses of the plurality of light-emitting layers may be the same or different.

For convenience of description, the entire film layer composed of a plurality of light-emitting layers and at least one connecting layer 40 is referred to as a light-emitting functional layer.

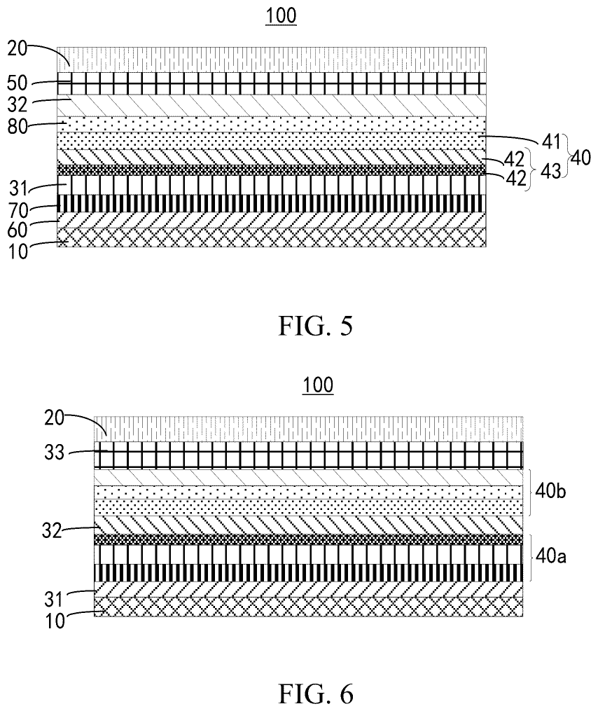

Referring to FIG. 5, in some embodiments, the light-emitting device 100 may further include an electronic functional layer 50 disposed between the light-emitting functional layer and the cathode 20. A material of the electron functional layer 50 includes an electron transport material including one or more of a metal oxide and a doped metal oxide. The metal oxide includes one or more of ZnO, TiO₂, and SnO₂; a metal oxide in the doped metal oxide includes one or more of ZnO, TiO₂, and SnO₂, and a doping element in the doped metal oxide includes one or more of Al, Mg, Li, In, and Ga. In some embodiments, a thickness of the electronic functional layer 50 ranges from 30 nm to 50 nm.

In some embodiments, the light-emitting device 100 may further include a hole functional layer disposed between the anode 10 and the light-emitting functional layer, the hole functional layer includes one or both of a first hole transport layer 70 and a hole injection layer 60, and when the hole functional layer includes the first hole transport layer 70 and the hole injection layer 60, the hole injection layer 60 is disposed between the anode 10 and the first hole transport layer 70. In some embodiments, a thickness of the first hole transport layer 70 ranges from 10 nm to 50 nm, and a thickness of the hole injection layer 60 ranges from 15 nm to 40 nm.

In some embodiments, the connecting layer 40 further includes a second hole transport layer 80 disposed on a side of the P-type layer 41 facing away from the N-type layer 43. In some embodiments, a thickness of the second hole transport layer 80 ranges from 15 nm to 40 nm.

A material of the first hole transport layer 70 and a material of the second hole transport layer 80 are each independently selected from one or more of 4,4′-N,N′-dicarbazole-biphenyl (CBP), poly[(9,9-dioctylfluorenyl-2,7-diyl)-co-(4,4′-(N-(4-sec-butylphenyl) diphenylamine)] (TFB), N,N′-Bis(naphthalen-1-yl)-N,N′-bis(phenyl)benzidine (α-NPD), N,N′-Bis(3-methylphenyl)-N,N′-bis(phenyl)benzidine (TPD), N,N′-Bis(3-methylphenyl)-N,N′-diphenyl-9,9-spirobifluorene-2,7-diamine (Spiro-TPD), N1,N1′-(Biphenyl-4,4′-diyl)bis(N1-phenyl-N4,N4-di-m-tolylbenzene-1,4-diamine) (DNTPD), 4,4′,4″-Tris(N-3-methylphenyl-N-phenylamino)triphenylamine (m-MTDATA), poly(p-phenyl vinyl) (PPV), poly[2-methoxy-5-(2-ethylhexyloxy)-1,4-phenylenevinylene] (MEH-PPV), poly[2-methoxy-5-(3′,7′-dimethyloctyloxy)-1,4-phenylenevinylene] (MOMO-PPV), 4,4′-Bis(N-carbazolyl)-1,1′-biphenyl, N,N,N′,N′-Tetraphenylbenzidine, PEDOT:PSS and its derivatives, poly(N-vinyl carbazole) (PVK) and its derivatives, poly(9,9-dioctylfluorene) and its derivatives, N,N′-bis(naphthalen-1-yl)-N,N′-diphenylbenzidine (NPB), and spiro NPB. The hole injection layer 60 may be selected from, but not limited to, at least one of polythiophene, polyaniline, 2,3,6,7,10,11-hexacyano-1,4,5,8,9,12-hexaazabenzophenanthrene, PEDOT, PEDOT:PSS, a derivative of PEDOT:PSS doped with s-MoO₃, 4,4′,4′-tris(N-3-methylphenyl-N-phenylamino) triphenylamine, tetracyanoquinone dimethane, copper phthalocyanine, nickel oxide (NiO), molybdenum oxide (MoO₃), tungsten oxide (WO₃), vanadium oxide (V₂O₅), molybdenum sulfide (MoS₃), tungsten sulfide (WS₃) and copper oxide (CuO).

It can be understood that in addition to the above-described functional layers, the light-emitting device 100 may also include some functional layers conventionally used for the light-emitting device 100 that contribute to improving the performance of the light-emitting device 100, such as an electron blocking layer, an electron injection layer, a hole blocking layer, and/or an interface modification layer.

It is understood that a material and a thickness of each layer of the light-emitting device 100 may be set and adjusted accordingly according to the light-emitting requirements of the light-emitting device 100.

It may be understood that the light-emitting device 100 may further include an encapsulation layer (not shown) to insulate water and oxygen (for example, to make the concentration of oxygen and water below 0.1 ppm) and improve the performance stability of the light-emitting device 100. Specifically, an encapsulation material used for forming the encapsulation layer may be at least one selected from UV glue, metal film, glass glue, and the like. In a specific embodiment, the encapsulating material may be acrylic resin or epoxy resin.

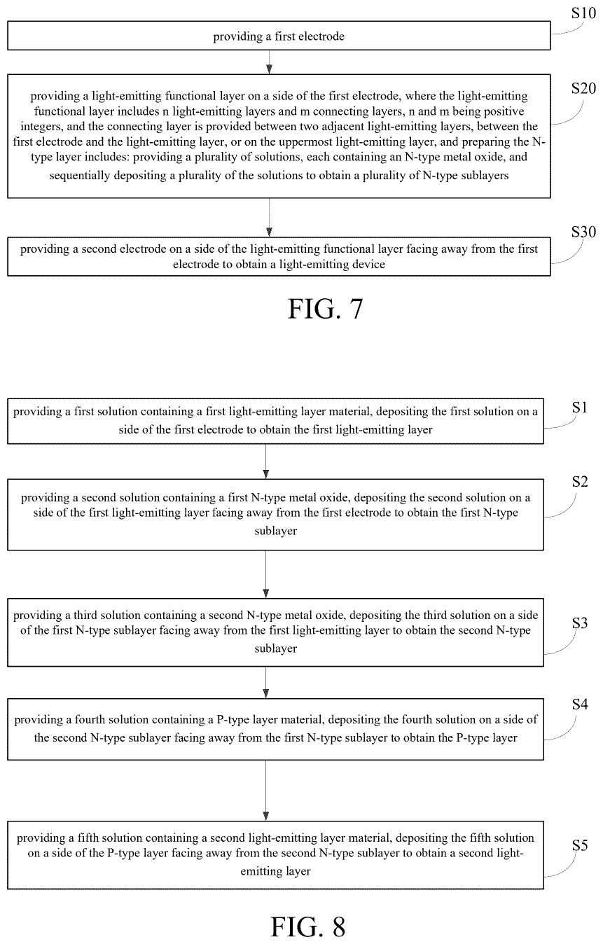

Referring to FIG. 7, in a second aspect, the present disclosure also provides a method for preparing a light emitting device 100, including:
S10, providing a first electrode;
S20, providing a light-emitting functional layer on a side of the first electrode, where the light-emitting functional layer includes n light-emitting layers and m connecting layers 40, n and m being positive integers, and the connecting layer 40 is provided between two adjacent light-emitting layers, between the first electrode and the light-emitting layer, or on the uppermost light-emitting layer, and preparing the N-type layer 43 includes: providing a plurality of solutions, each containing an N-type metal oxide, and sequentially depositing a plurality of the solutions to obtain a plurality of N-type sublayers 42;
S30, providing a second electrode on a side of the light-emitting functional layer facing away from the first electrode to obtain a light-emitting device 100.

In some embodiments, the connecting layer 40 further includes a P-type layer 41 stacked on a side of the plurality of N-type sublayers 42. The N-type layer 43 is disposed close to the anode 10, and the P-type layer 41 is disposed close to the cathode 20.

In some embodiments, in the N-type layer 43, an average particle size of the N-type metal oxide contained in the N-type sublayer 42 closest to the cathode 20 is larger than an average particle size of the N-type metal oxide contained in the N-type sublayer 42 farthest from the cathode 20. In the N-type layer 43, a band gap width of the N-type metal oxide contained in the N-type sublayer 42 closest to the cathode 20 is smaller than a band gap width of the N-type metal oxide contained in the N-type sublayer 42 farthest from the cathode 20.

Briefly, the method of preparing the light-emitting device 100 may include preparing a plurality of film layers sequentially from bottom to top, following a film layer stacking order of the light-emitting device 100 as described above, to obtain the light-emitting device 100. The plurality of film layers refer to the anode 10, the cathode 20, and the functional layer. The film layer stacking order may be that the anode 10, the functional layer, and the cathode 20 are stacked in this order from bottom to top, or it may be that the cathode 20, the light-emitting functional layer, and the anode 10 are stacked in this order from bottom to top. When the light-emitting device 100 further includes other film layers such as the electron functional layer 50, the first hole transport layer 70, and the hole injection layer 60, the other film layers may be prepared at the corresponding film layer positions according to the film layer lamination order described above. For example, in some embodiments, when the device structure is an anode 10, a hole injection layer 60, a first hole transport layer 70, a first light-emitting layer 31, a first N-type sublayer, a second N-type sublayer, a P-type layer 41, a second hole transport layer 80, a second light-emitting layer 32, an electron functional layer 50, and a cathode 20 that are stacked in this order from bottom to top, the anode 10, the hole injection layer 60, the first hole transport layer 70, the first light-emitting layer 31, the first N-type sublayer, the second N-type sublayer, the P-type layer 41, the second hole transport layer 80, the second light-emitting layer 32, the electron functional layer 50, and the cathode 20 may be prepared in this order.

It can be understood that each film layer in the light-emitting device 100 provided by the present disclosure, including the anode 10, the cathode 20, the functional layer, and other film layers, may be prepared by conventional techniques in the field, such as chemical methods or physical methods. Among them, the chemical methods include chemical vapor deposition method, continuous ion layer adsorption and reaction method, anodic oxidation method, electrolytic deposition method and co-precipitation method. The physical methods include a physical coating method and a solution method. The physical coating method includes: a thermal evaporation coating method, an electron beam evaporation coating method, a magnetron sputtering method, a multi-arc ion coating method, a physical vapor deposition method, an atomic layer deposition method, a pulsed laser deposition method, and the like. The solution method may be a spin coating method, a printing method, an ink jet printing method, a blade coating method, a printing method, a dipping and pulling method, a soaking method, a spray coating method, a roll coating method, a casting method, a slit coating method, a strip coating method, or the like. In some embodiments, the N-type layer 43 and the P-type layer 41 are prepared using the solution method.

In order to prevent a solvent from attacking the previous N-type sublayer 42 when the next N-type sublayer 42 is prepared, the solvents in the solutions corresponding to two adjacent N-type sublayers 42 are orthogonal. Similarly, in order to prevent a solvent used for the P-type layer 41 from attacking the adjacent N-type sublayer 42, or a solvent used for the adjacent N-type sublayer 42 from attacking the P-type layer 41, the corresponding solvent of the P-type layer 41 is orthogonal to the corresponding solvent of the adjacent N-type sublayer 42. In this way, using different solvent systems to prepare adjacent film layers can enhance the anti-solvent characteristics of each film layer of the connecting layer 40 and improve device stability.

In some specific embodiments, the light-emitting functional layer includes a first light-emitting layer 31, a first N-type sublayer, a second N-type sublayer, a P-type layer 41, and a second light-emitting layer 32. Referring to FIG. 8, the method of preparing the light-emitting functional layer includes:
S1, providing a first solution containing a first light-emitting layer material, depositing the first solution on a side of the first electrode to obtain the first light-emitting layer 31;
S2, providing a second solution containing a first N-type metal oxide, depositing the second solution on a side of the first light-emitting layer 31 facing away from the first electrode to obtain the first N-type sublayer;
S3, providing a third solution containing a second N-type metal oxide, depositing the third solution on a side of the first N-type sublayer facing away from the first light-emitting layer 31 to obtain the second N-type sublayer;
S4, providing a fourth solution containing a P-type layer material, depositing the fourth solution on a side of the second N-type sublayer facing away from the first N-type sublayer to obtain the P-type layer 41;
S5, providing a fifth solution containing a second light-emitting layer material, depositing the fifth solution on a side of the P-type layer 41 facing away from the second N-type sublayer to obtain a second light-emitting layer 32.

Among them, an average particle size of the first N-type metal oxide is smaller than an average particle size of the second N-type metal oxide; and a band gap width of the first N-type metal oxide is greater than a band gap width of the second N-type metal oxide. Specifically, in some embodiments, the average particle size of the first N-type metal oxide is 2-5 nm; the average particle size of the second N-type metal oxide is 5-8 nm. The band gap width of the first N-type metal oxide is 3.6 to 4.2 ev; and the band gap width of the second N-type metal oxide is 3.2 to 3.6 ev.

In some embodiments, the second solution further includes a first polar solvent, which may include, but is not limited to, one or more of methanol, ethanol, isopropanol, 2-methoxyethanol, benzyl alcohol, and cyclopentanol.

In some embodiments, the third solution further includes a non-polar solvent, which may include, but is not limited to, one or more of one or more of cyclopentanone, toluene, cyclohexylbenzene, chlorobenzene, and octadecane.

In some embodiments, the fourth solution includes a second polar solvent, which may include, but is not limited to, one or more of methanol, ethanol, isopropanol, 2-methoxyethanol, benzyl alcohol, and cyclopentanol.

The P-type layer material may include, but is not limitede to, at least one of polythiophene, polyaniline, 2,3,6,7,10,11-hexacyano-1,4,5,8,9,12-hexaazabenzophenanthrene, PEDOT, PEDOT:PSS, a derivative of PEDOT:PSS doped with s-MoO₃, 4,4′,4′-tris(N-3-methylphenyl-N-phenylamino) triphenylamine, tetracyanoquinone dimethane, copper phthalocyanine, nickel oxide, molybdenum oxide, tungsten oxide, vanadium oxide, molybdenum sulfide, tungsten sulfide and copper oxide.

The first light-emitting layer material and the second light-emitting layer material are independently selected from quantum dot light-emitting materials, and the quantum dot light-emitting materials may be any one or more of the quantum dot light-emitting materials described above, which will not be described herein. The first light-emitting layer material and the second light-emitting layer material may be the same or different. It is understood that a solvent contained in the first solution and a solvent contained in the second solution may be orthogonal solvents to each other, and a solvent contained in the third solution and a solvent contained in the fourth solution may be orthogonal solvents to each other. Specifically, the solvent contained in the first solution may be an alkane solvent such as n-pentane, n-hexane, cyclopentane, cyclohexane, and the like; the solvent contained in the fifth solution may be an alkane solvent such as n-pentane, n-hexane, cyclopentane, cyclohexane, and the like.

In a third aspect, the present disclosure also relates to a display device including an optoelectronic device 100 described above, or the light-emitting device 100 prepared by the method described above. The display device may be any electronic product having a display function, and the electronic product includes, but is not limited to, a smartphone, a tablet computer, a notebook computer, a digital camera, a digital video camera, a smart wearable device, a smart weighing electronic scale, a vehicle-mounted display, a television, or an electronic book reader. The smart wearable device may be, for example, a smart bracelet, a smart watch, a Virtual Reality (VR) helmet, or the like.

Hereinafter, the present disclosure will be specifically described with reference to specific examples, and the following examples are only partial examples of the present disclosure and do not limit the present disclosure. The raw materials used in the following examples are commercially available products unless otherwise specified.

### Example 1

The structure of the QLED device provided in this embodiment and the materials of each layer are shown in the following table:

TABLE 1-1

| | | Material Properties | | | |
|---|---|---|---|---|---|
| | | average | band | | |
| | | particle | gap | | thickness |
| | Material | size | width | | of layer |
| | Type | (nm) | (ev) | solvent | (nm) |
| anode | ITO | / | / | / | 100 |
| hole injection | PEDOT:PSS | / | / | / | 30 |
| layer | | | | | |
| first hole | TFB | / | / | chlorobenzene | 20 |
| transport layer | | | | | |
| first light- | Blue QDs: ZnSe | / | / | cyclohexane | 20 |
| emitting layer | | | | | |
| first N-type | Zn_{0.9}Mg_{0.1}O | 3.5 | 3.9 | ethanol | 10 |
| sublayer | | | | | |
| second N-type | ZnO | 8 | 3.3 | toluene | 25 |
| sublayer | | | | | |
| P-type layer | PEDOT:PSS | / | / | / | 30 |
| second hole | TFB | / | / | chlorobenzene | 25 |
| transport layer | | | | | |
| second light- | Blue QDs: ZnSe | / | / | cyclohexane | 20 |
| emitting layer | | | | | |
| Electron | Zn_{0.95}Mg_{0.05}O | / | / | ethanol | 30 |
| transport layer | | | | | |
| cathode | Ag | / | / | / | 100 |

The method of preparing the device includes steps as follows.

(1) In a step of preparing a first N-type sublayer material solution, Zinc acetate and magnesium acetate were dissolved in an ethanol solvent according to a molar ratio of 9:1 to prepare a first precursor solution having a total concentration of zinc acetate and magnesium acetate of 0.5 mmol/ml. Potassium hydroxide was dissolved in an ethanol solvent to prepare a potassium hydroxide solution having a concentration of 0.5 mmol/ml. The potassium hydroxide solution was added to the first precursor solution, and then a reaction was carried out at 40° C. for 2 h to obtain a reaction mixture. The reaction mixture was precipitated using an excess of an ethyl acetate solvent to obtain ZMO nanoparticles. The ZMO nanoparticles had a chemical formula of Zn_{0.9}Mg_{0.10}, an average particle size of 3.5 nm, and a band gap width of 3.9 eV. The prepared ZMO nanoparticles were dispersed in ethanol to prepare the first N-type sublayer material solution with a ZMO nanoparticle concentration of 40 mg/mL for later use.

In a step of preparing a second N-type sublayer material solution. Zinc stearate was dispersed in N-octadecane to obtain a second precursor solution having a concentration of 0.2 mmol/ml. 4,4′-diaminodiphenyl ether was dissolved in n-octadecane to obtain a third precursor solution with a concentration of 0.2 mmol/ml. The second precursor solution and the third precursor solution were mixed at a volume ratio of 1:5, and a reaction was carried out at 210° C. for 1 h to obtain a reaction mixture. The reaction mixture was precipitated using an excess butanol to obtain ZnO nanoparticles. The ZnO nanoparticles had a chemical formula of ZnO, an average particle size of 8 nm, and a band gap width of 3.3 eV. The prepared ZnO nanoparticles were dispersed in toluene to prepare the second N-type sublayer material solution with a ZnO nanoparticle concentration of 30 mg/mL for later use.

(2) the ITO anode substrate was cleaned and then treated under UV conditions for 15 min as an anode. Then, PEDOT:PSS was spin-coated onto the processed ITO substrate to a thickness of 30 nm to obtain a hole injection layer.

(3) A TFB chlorobenzene solution was spin-coated on the hole injection layer to obtain a first hole transport layer having a thickness of 20 nm.

(4) A cyclohexane solution having blue quantum dots ZnSe was spin-coated on the hole transport layer to obtain a first light-emitting layer having a thickness of 20 nm. A light-emitting wavelength of the blue quantum dots ZnSe was 470 nm.

(5) The first N-type sublayer material solution obtained in the step (1) was spin-coated on the first light-emitting layer to obtain a first N-type sublayer having a thickness of 10 nm. The second N-type sublayer material solution obtained in the step (1) was spin-coated on the first N-type sublayer to obtain a second N-type sublayer with a thickness of 25 nm. PEDOT:PSS was spin-coated on the second N-type sublayer to obtain a P-type layer having a thickness of 30 nm. The TFB chlorobenzene solution was spin-coated on the P-type layer to obtain a second hole transport layer having a thickness of 25 nm.

The first N-type sublayer, the second N-type sublayer, the P-type layer, and the second hole transport layer together constitute a connecting layer.

(6) The cyclohexane solution having blue quantum dots ZnSe was spin-coated on the second hole transport layer to obtain a second light-emitting layer having a thickness of 20 nm. A light-emitting wavelength of the blue quantum dots ZnSe was 470 nm.

(7) A solution having Zn_{0.95}Mg_{0.05}O and ethanol was spin-coated on the second light-emitting layer to obtain an electron transport layer having a thickness of 30 nm.

(8) A cathode was obtained by vacuum evaporation deposition of Ag with a thickness of 100 nm on the electron transport layer, and then encapsulation was performed to obtain a light emitting device.

Among them, methods of detecting an average particle size and a band gap width were as follows:

Transmission electron microscope (TEM) was used to observe a material to obtain the average particle size of the material; X-ray photoelectron spectroscopy (XPS) and ultraviolet photoelectron spectroscopy (UPS) were used to detect the energy level of the material, and the band gap width value of the materials was obtained.

### Example 2

Example 2 is basically the same as Example 1, except that in Example 2:

The structure of the provided QLED devices and the materials of each layer are shown in the following table.

TABLE 1-2

| | | Material Properties | | | |
|---|---|---|---|---|---|
| | | average | band | | |
| | | particle | gap | | thickness |
| | | size | width | | of layer |
| | Material Type | (nm) | (ev) | solvent | (nm) |
| anode | ITO | / | / | / | 100 |
| hole injection layer | PEDOT:PSS | / | / | / | 30 |
| first hole transport | TFB | / | / | chlorobenzene | 20 |
| layer | | | | | |
| first light-emitting | Blue QDs:ZnSe | / | / | cyclohexane | 20 |
| layer | | | | | |
| first N-type | Zn_{0.85}Mg_{0.15}O | 2.5 | 3.93 | ethanol | 10 |
| sublayer | | | | | |
| second N-type | ZnO | 8 | 3.3 | toluene | 25 |
| sublayer | | | | | |
| P-type layer | PEDOT:PSS | / | / | / | 30 |
| second hole | TFB | / | / | chlorobenzene | 25 |
| transport layer | | | | | |
| second light- | Blue QDs:ZnSe | / | / | cyclohexane | 20 |
| emitting layer | | | | | |
| Electron transport | Zn_{0.95}Mg_{0.05}O | / | / | ethanol | 30 |
| layer | | | | | |
| cathode | Ag | / | / | / | 100 |

Accordingly, in the method:

The step (1) of preparing the first N-type sublayer material solution is as follows. Zinc acetate and magnesium acetate were dissolved in an ethanol solvent according to a molar ratio of 85:15 to prepare a first precursor solution having a total concentration of zinc acetate and magnesium acetate of 0.5 mmol/ml. Potassium hydroxide was dissolved in an ethanol solvent to prepare a potassium hydroxide solution having a concentration of 0.5 mmol/ml. The potassium hydroxide solution was added to the first precursor solution, and then a reaction was carried out at 26° C. for 24 h to obtain a reaction mixture. The reaction mixture was precipitated using an excess of an ethyl acetate solvent to obtain ZMO nanoparticles. The ZMO nanoparticles had a chemical formula of Zn0.85Mg0.15O, an average particle size of 2.5 nm, and a band gap width of 3.93 eV. The prepared ZMO nanoparticles were dispersed in ethanol to prepare the first N-type sublayer material solution with a ZMO nanoparticle concentration of 40 mg/mL for later use.

### Example 3

Example 3 is basically the same as Example 1, except that in Example 3:

The structure of the provided QLED devices and the materials of each layer are shown in the following table.

TABLE 1-3

| | | Material Properties | | | |
|---|---|---|---|---|---|
| | | average | band | | |
| | | particle | gap | | thickness |
| | | size | width | | of layer |
| | Material Type | (nm) | (ev) | solvent | (nm) |
| anode | ITO | / | / | / | 100 |
| hole injection layer | PEDOT:PSS | / | / | / | 30 |
| first hole transport | TFB | / | / | chlorobenzene | 20 |
| layer | | | | | |
| first light-emitting | Blue QDs:ZnSe | / | / | cyclohexane | 20 |
| layer | | | | | |
| first N-type | ZnO | 5 | 3.6 | ethanol | 10 |
| sublayer | | | | | |
| second N-type | ZnO | 8 | 3.3 | toluene | 25 |
| sublayer | | | | | |
| P-type layer | PEDOT:PSS | / | / | / | 30 |
| second hole | TFB | / | / | chlorobenzene | 25 |
| transport layer | | | | | |
| second light- | Blue QDs:ZnSe | / | / | cyclohexane | 20 |
| emitting layer | | | | | |
| Electron transport | Zn_{0.95}Mg_{0.05}O | / | / | ethanol | 30 |
| layer | | | | | |
| cathode | Ag | / | / | / | 100 |

Accordingly, in the method:

The step (1) of preparing the first N-type sublayer material solution was as follows. Zinc acetate was dissolved in ethanol solvent to prepare a precursor solution with a concentration of 0.5 mmol/ml. Tetramethyl ammonia hydroxide was dissolved in ethanol solvent to prepare an alkali solution with a concentration of 0.5 mmol/ml. The alkali solution was added to the precursor solution, and then a reaction was carried out at a room temperature (26° C.) for 2 h to obtain a reaction mixture. The reaction mixture was precipitated using an excess of ethyl acetate solvent to obtain ZnO nanoparticles. The ZnO nanoparticles had a chemical formula of ZnO, an average particle size of 5 nm, and a band gap width of 3.6 eV. The prepared ZnO nanoparticles were dispersed in ethanol to prepare the first N-type sublayer material solution with a ZnO nanoparticle concentration of 40 mg/mL for later use.

### Example 4

Example 4 is basically the same as Example 1, except that in Example 4:

The structure of the provided QLED devices and the materials of each layer are shown in the following table.

TABLE 1-4

| | | Material Properties | | | |
|---|---|---|---|---|---|
| | | average | band | | |
| | | particle | gap | | thickness |
| | | size | width | | of layer |
| | Material Type | (nm) | (ev) | solvent | (nm) |
| anode | ITO | / | / | / | 100 |
| hole injection layer | PEDOT:PSS | / | / | / | 30 |
| first hole transport | TFB | / | / | chlorobenzene | 20 |
| layer | | | | | |
| first light-emitting | Blue QDs:ZnSe | / | / | cyclohexane | 20 |
| layer | | | | | |
| first N-type | Zn_{0.9}Mg_{0.1}O | 3.5 | 3.9 | ethanol | 10 |
| sublayer | | | | | |
| second N-type | ZnO | 5 | 3.4 | toluene | 25 |
| sublayer | | | | | |
| P-type layer | PEDOT:PSS | / | / | / | 30 |
| second hole | TFB | / | / | chlorobenzene | 25 |
| transport layer | | | | | |
| second light- | Blue QDs:ZnSe | / | / | cyclohexane | 20 |
| emitting layer | | | | | |
| Electron transport | Zn_{0.95}Mg_{0.05}O | / | / | ethanol | 30 |
| layer | | | | | |
| cathode | Ag | / | / | / | 100 |

Accordingly, in the method:

The step (1) of preparing the second N-type sublayer material solution was as follows. Zinc acetate was dissolved in ethanol solvent to prepare a precursor solution with a concentration of 0.5 mmol/ml. Tetramethyl ammonia hydroxide was dissolved in ethanol solvent to prepare an alkali solution with a concentration of 0.5 mmol/ml. The alkali solution was added to the precursor solution, and then a reaction was carried out at a room temperature for 2 h to obtain a reaction mixture. The reaction mixture was precipitated using an excess of ethyl acetate solvent to obtain a precipitate. The precipitate was dissolved in butanol, and then thiol with a concentration of 10 mmol/ml was added. A reaction was carried out at a room temperature for 20 hours, and ethyl acetate was added for precipitation to obtain ZnO nanoparticles. The ZnO nanoparticles had a chemical formula of ZnO, an average particle size of 5 nm, and a band gap width of 3.4 eV. The prepared ZnO nanoparticles were dispersed in toluene to prepare the second N-type sublayer material solution with a ZnO nanoparticle concentration of 40 mg/mL for later use.

### Example 5

Example 5 is basically the same as Example 1, except that in Example 5:

The structure of the provided QLED devices and the materials of each layer are shown in the following table.

TABLE 1-5

| | | Material Properties | | | |
|---|---|---|---|---|---|
| | | average | band | | |
| | | particle | gap | | thickness |
| | | size | width | | of layer |
| | Material Type | (nm) | (ev) | solvent | (nm) |
| anode | ITO | / | / | / | 100 |
| hole injection layer | PEDOT:PSS | / | / | / | 30 |
| first hole transport | TFB | / | / | chlorobenzene | 20 |
| layer | | | | | |
| first light-emitting | Blue QDs:ZnSe | / | / | cyclohexane | 20 |
| layer | | | | | |
| first N-type | Zn_{0.9}Mg_{0.1}O | 3.5 | 3.9 | ethanol | 10 |
| sublayer | | | | | |
| second N-type | ZnO | 10 | 3.3 | toluene | 25 |
| sublayer | | | | | |
| P-type layer | PEDOT:PSS | / | / | / | 30 |
| second hole | TFB | / | / | chlorobenzene | 25 |
| transport layer | | | | | |
| second light- | Blue QDs:ZnSe | / | / | cyclohexane | 20 |
| emitting layer | | | | | |
| Electron transport | Zn_{0.95}Mg_{0.05}O | / | / | ethanol | 30 |
| layer | | | | | |
| cathode | Ag | / | / | / | 100 |

Accordingly, in the method:

The step (1) of preparing the second N-type sublayer material solution was as follows. Zinc stearate was dispersed in N-octadecane to obtain a second precursor solution having a concentration of 0.2 mmol/ml. 4,4′-diaminodiphenyl ether was dissolved in n-octadecane to obtain a third precursor solution with a concentration of 0.2 mmol/ml. The second precursor solution and the third precursor solution were mixed at a volume ratio of 1:5, and a reaction was carried out at 250° C. for 3 h to obtain a reaction mixture. The reaction mixture was precipitated using an excess butanol to obtain ZnO nanoparticles. The ZnO nanoparticles had a chemical formula of ZnO, an average particle size of 10 nm, and a band gap width of 3.3 eV. The prepared ZnO nanoparticles were dispersed in toluene to prepare the second N-type sublayer material solution with a ZnO nanoparticle concentration of 30 mg/mL for later use.

### Example 6

Example 6 is basically the same as Example 1, except that in Example 6:

The structure of the provided QLED devices and the materials of each layer are shown in the following table.

TABLE 1-6

| | | Material Properties | | | |
|---|---|---|---|---|---|
| | | average | band | | |
| | | particle | gap | | thickness |
| | | size | width | | of layer |
| | Material Type | (nm) | (ev) | solvent | (nm) |
| anode | ITO | / | / | / | 100 |
| hole injection layer | PEDOT:PSS | / | / | / | 30 |
| first hole transport | TFB | / | / | chlorobenzene | 20 |
| layer | | | | | |
| first light-emitting | Blue QDs:ZnSe | / | / | cyclohexane | 20 |
| layer | | | | | |
| first N-type | Zn_{0.9}Mg_{0.1}O | 3.5 | 3.9 | ethanol | 13 |
| sublayer | | | | | |
| second N-type | ZnO | 8 | 3.3 | toluene | 13 |
| sublayer | | | | | |
| P-type layer | PEDOT:PSS | / | / | / | 30 |
| second hole | TFB | / | / | chlorobenzene | 25 |
| transport layer | | | | | |
| second light- | Blue QDs:ZnSe | / | / | cyclohexane | 20 |
| emitting layer | | | | | |
| Electron transport | Zn_{0.95}Mg_{0.05}O | / | / | ethanol | 30 |
| layer | | | | | |
| cathode | Ag | / | / | / | 100 |

Accordingly, in step (5) of the method:

the thickness of the first N-type sublayer is changed to 13 nm, and the thickness of the second N-type sublayer is changed to 13 nm.

### Example 7

Example 7 is basically the same as Example 1, except that in Example 7:

The structure of the provided QLED devices and the materials of each layer are shown in the following table.

TABLE 1-7

| | | Material Properties | | | |
|---|---|---|---|---|---|
| | | average | band | | |
| | | particle | gap | | thickness |
| | | size | width | | of layer |
| | Material Type | (nm) | (ev) | solvent | (nm) |
| anode | ITO | / | / | / | 100 |
| hole injection layer | PEDOT:PSS | / | / | / | 30 |
| first hole transport | TFB | / | / | chlorobenzene | 20 |
| layer | | | | | |
| first light-emitting | Blue QDs:ZnSe | / | / | cyclohexane | 20 |
| layer | | | | | |
| first N-type | Zn_{0.9}Mg_{0.1}O | 3.5 | 3.9 | ethanol | 25 |
| sublayer | | | | | |
| second N-type | ZnO | 8 | 3.3 | toluene | 10 |
| sublayer | | | | | |
| P-type layer | PEDOT:PSS | / | / | / | 30 |
| second hole | TFB | / | / | chlorobenzene | 25 |
| transport layer | | | | | |
| second light- | Blue QDs:ZnSe | / | / | cyclohexane | 20 |
| emitting layer | | | | | |
| Electron transport | Zn_{0.95}Mg_{0.05}O | / | / | ethanol | 30 |
| layer | | | | | |
| cathode | Ag | / | / | / | 100 |

Accordingly, in step (5) of the method:
the thickness of the first N-type sublayer is changed to 25 nm, and the thickness of the second N-type sublayer is changed to 10 nm.

### Example 8

Example 8 is basically the same as Example 1, except that in Example 8:

The structure of the provided QLED devices and the materials of each layer are shown in the following table.

TABLE 1-8

| | | Material Properties | | | |
|---|---|---|---|---|---|
| | | average | band | | |
| | | particle | gap | | thickness |
| | | size | width | | of layer |
| | Material Type | (nm) | (ev) | solvent | (nm) |
| anode | ITO | / | / | / | 100 |
| hole injection layer | PEDOT:PSS | / | / | / | 30 |
| first hole transport | TFB | / | / | chlorobenzene | 20 |
| layer | | | | | |
| first light-emitting | Blue QDs:ZnSe | / | / | cyclohexane | 20 |
| layer | | | | | |
| first N-type | Zn_{0.9}Mg_{0.1}O | 3.5 | 3.9 | ethanol | 10 |
| sublayer | | | | | |
| second N-type | ZnO | 8 | 3.3 | toluene | 10 |
| sublayer | | | | | |
| Third N-type | SnO₂ | 10 | 3.2 | ethanol | 15 |
| sublayer | | | | | |
| P-type layer | PEDOT:PSS | / | / | / | 30 |
| second hole | TFB | / | / | chlorobenzene | 25 |
| transport layer | | | | | |
| second light- | Blue QDs:ZnSe | / | / | cyclohexane | 20 |
| emitting layer | | | | | |
| Electron transport | Zn_{0.95}Mg_{0.5}O | / | / | ethanol | 30 |
| layer | | | | | |
| cathode | Ag | / | / | / | 100 |

Accordingly, in the method:

the step (1) also includes the step of preparing a third N-type sublayer material solution. In a mixed solution of ethanol and water (volume ratio 4:1), tin chloride pentahydrate was added to obtain a precursor solution with a concentration of 0.04 mol/ml. Then, 0.1 mol/ml sodium hydroxide ethanol solution equal to the precursor solution was added to the precursor solution, and the reaction was carried out at 140° C. for 5 hours to obtain a reaction mixture. The reaction mixture was precipitated using ethyl acetate to obtain SnO₂ nanoparticles. The SnO₂ nanoparticles had an average particle size of 10 nm, and a band gap width of 3.2 eV. The prepared SnO₂ nanoparticles were dispersed in ethanol to prepare the third N-type sublayer material solution with a SnO₂ nanoparticle concentration of 30 mg/mL for later use.

In step (5), the thickness of the second N-type sublayer is changed to 10 nm.

And after the step of preparing the second N-type sublayer, the step further includes: the third N-type sublayer material solution was spin-coated on the second N-type sublayer to obtain a third N-type sublayer with a thickness of 15 nm, and the upper surface of the third N-type sublayer was used for spin-coating PEDOT:PSS to prepare the P-type layer.

### Example 9

Example 9 is basically the same as Example 1, except that in Example 9:

The structure of the provided QLED devices and the materials of each layer are shown in the following table.

TABLE 1-9

| | | Material Properties | | | |
|---|---|---|---|---|---|
| | | average | band | | |
| | | particle | gap | | thickness |
| | | size | width | | of layer |
| | Material Type | (nm) | (ev) | solvent | (nm) |
| anode | ITO | / | / | / | 100 |
| hole injection layer | PEDOT:PSS | / | / | / | 30 |
| first hole transport | TFB | / | / | chlorobenzene | 20 |
| layer | | | | | |
| first light-emitting | Blue QDs:ZnSe | / | / | cyclohexane | 20 |
| layer | | | | | |
| first N-type | Zn_{0.9}Mg_{0.1}O | 3.5 | 3.9 | ethanol | 10 |
| sublayer a | | | | | |
| second N-type | ZnO | 8 | 3.3 | toluene | 25 |
| sublayer a | | | | | |
| P-type layer a | PEDOT:PSS | / | / | / | 30 |
| second hole | TFB | / | / | chlorobenzene | 25 |
| transport layer | | | | | |
| second light- | Blue QDs:ZnSe | / | / | cyclohexane | 20 |
| emitting layer | | | | | |
| first N-type | Zn_{0.9}Mg_{0.1}O | 3.5 | 3.9 | ethanol | 10 |
| sublayer b | | | | | |
| second N-type | ZnO | 8 | 3.3 | toluene | 25 |
| sublayer b | | | | | |
| P-type layer b | PEDOT:PSS | / | / | / | 30 |
| third hole transport | TFB | / | / | chlorobenzene | 25 |
| layer | | | | | |
| third light-emitting | Blue QDs:ZnSe | / | / | cyclohexane | 20 |
| layer | | | | | |
| Electron transport | Zn_{0.95}Mg_{0.05}O | / | / | ethanol | 30 |
| layer | | | | | |
| cathode | Ag | / | / | / | 100 |

Accordingly, in the method:
after the step of preparing the second light-emitting layer, the step (6) further includes step (6-1).

In step (6-1), the first N-type sublayer material solution obtained in the step (1) was spin-coated on the second light-emitting layer to obtain a first N-type sublayer b having a thickness of 25 nm. The second N-type sublayer material solution obtained in the step (1) was spin-coated on the first N-type sublayer b to obtain the second N-type sublayer b having a thickness of 10 nm. PEDOT:PSS was spin-coated on the second N-type sublayer b to obtain a P-type layer b having a thickness of 30 nm. And the TFB chlorobenzene solution was spin-coated on the P-type layer b to obtain a third hole transport layer having a thickness of 25 nm.

The cyclohexane solution having blue quantum dots ZnSe, wherein the emission wavelength of the blue quantum dots ZnSe was 470 nm, was spin-coated on the third hole transport layer to obtain a third light-emitting layer having a thickness of 20 nm.

### Example 10

Example 6 is basically the same as Example 1, except that in Example 10:

The structure of the provided QLED devices and the materials of each layer are shown in the following table.

TABLE 1-10

| | | Material Properties | | | |
|---|---|---|---|---|---|
| | | average | band | | |
| | | particle | gap | | thickness |
| | | size | width | | of layer |
| | Material Type | (nm) | (ev) | solvent | (nm) |
| anode | ITO | / | / | / | 100 |
| hole injection layer | PEDOT:PSS | / | / | / | 30 |
| first hole transport | TFB | / | / | chlorobenzene | 20 |
| layer | | | | | |
| first light-emitting | Red QDs:CdZnSe/ | / | / | cyclohexane | 20 |
| layer | ZnSe/ZnS | | | | |
| first N-type | Zn_{0.9}Mg_{0.1}O | 3.5 | 3.9 | ethanol | 10 |
| sublayer | | | | | |
| second N-type | ZnO | 8 | 3.3 | toluene | 25 |
| sublayer | | | | | |
| P-type layer | PEDOT:PSS | / | / | / | 30 |
| second hole | TFB | / | / | chlorobenzene | 25 |
| transport layer | | | | | |
| second light- | Red QDs:CdZnSe/ | / | / | cyclohexane | 20 |
| emitting layer | ZnSe/ZnS | | | | |
| Electron transport | Zn_{0.95}Mg_{0.05}O | / | / | ethanol | 30 |
| layer | | | | | |
| cathode | Ag | / | / | / | 100 |

Correspondingly, in steps (4) and (6) of the method, the blue quantum dots are changed to red quantum dots CdZnSe/ZnSe/ZnS. The emission wavelength of the red quantum dots is 630 nm.

### Comparative Example 1

Comparative Example 1 is basically the same as Example 1, except that the QLED device provided in Comparative Example 1 has only one N-type layer (without the second N-type sublayer), and its specific structure and materials of each layer are shown in the following table:

TABLE 1-11

| | | Material Properties | | | |
|---|---|---|---|---|---|
| | | average | band | | |
| | | particle | gap | | thickness |
| | | size | width | | of layer |
| | Material Type | (nm) | (ev) | solvent | (nm) |
| anode | ITO | / | / | / | 100 |
| hole injection layer | PEDOT:PSS | / | / | / | 30 |
| first hole transport | TFB | / | / | chlorobenzene | 20 |
| layer | | | | | |
| first light-emitting | Blue QDs:ZnSe | / | / | cyclohexane | 20 |
| layer | | | | | |
| first N-type | Zn_{0.9}Mg_{0.1}O | 3.5 | 3.9 | ethanol | 35 |
| sublayer | | | | | |
| P-type layer | PEDOT:PSS | / | / | / | 30 |
| second hole | TFB | / | / | chlorobenzene | 25 |
| transport layer | | | | | |
| second light- | Blue QDs:ZnSe | / | / | cyclohexane | 20 |
| emitting layer | | | | | |
| Electron transport | Zn_{0.95}Mg_{0.05}O | / | / | ethanol | 30 |
| layer | | | | | |
| cathode | Ag | / | / | / | 100 |

Accordingly, step (5) of the method is as follows.

The first N-type sublayer material solution obtained in the step (1) was spin-coated on the first light-emitting layer to obtain a first N-type sublayer with a thickness of 35 nm. PEDOT:PSS was spin-coated on the first N-type sublayer to obtain a P-type layer having a thickness of 30 nm. A TFB chlorobenzene solution was spin-coated on the P-type layer to obtain a second hole transport layer having a thickness of 25 nm. The first N-type sublayer, the P-type layer, and the second hole transport layer together constitute a connecting layer.

### Comparative Example 2

Comparative Example 2 is basically the same as Example 1, except that the QLED device provided in Comparative Example 2 has only one N-type layer (without the first N-type sublayer), and its specific structure and materials of each layer are shown in the following table:

TABLE 1-12

| | | Material Properties | | | |
|---|---|---|---|---|---|
| | | average | band | | |
| | | particle | gap | | thickness |
| | | size | width | | of layer |
| | Material Type | (nm) | (ev) | solvent | (nm) |
| anode | ITO | / | / | / | 100 |
| hole injection layer | PEDOT:PSS | / | / | / | 30 |
| first hole transport | TFB | / | / | chlorobenzene | 20 |
| layer | | | | | |
| first light-emitting | Blue QDs:ZnSe | / | / | cyclohexane | 20 |
| layer | | | | | |
| second N-type | ZnO | 8 | 3.3 | toluene | 35 |
| sublayer | | | | | |
| P-type layer | PEDOT:PSS | / | / | / | 30 |
| second hole | TFB | / | / | chlorobenzene | 25 |
| transport layer | | | | | |
| second light- | Blue QDs:ZnSe | / | / | cyclohexane | 20 |
| emitting layer | | | | | |
| Electron transport | Zn_{0.95}Mg_{0.05}O | / | / | ethanol | 30 |
| layer | | | | | |
| cathode | Ag | / | / | / | 100 |

Accordingly, step (5) of the preparation method is as follows.

The second N-type sublayer material solution obtained in the step (1) was spin-coated on the first light-emitting layer to obtain a second N-type sublayer with a thickness of 35 nm. PEDOT:PSS was spin-coated on the second N-type sublayer to obtain a P-type layer having a thickness of 30 nm. A TFB chlorobenzene solution was spin-coated on the P-type layer to obtain a second hole transport layer having a thickness of 25 nm. The second N-type sublayer, the P-type layer, and the second hole transport layer together constitute a connecting layer.

### Comparative Example 3

Comparative Example 3 is basically the same as that of Example 1, except that in the QLED device provided in Comparative Example 3, the stacking order of the first N-type sublayer and the second N-type sublayer is reversed, and the specific structure and materials of each layer are shown in the following table:

TABLE 1-13

| | | Material Properties | | | |
|---|---|---|---|---|---|
| | | average | band | | |
| | | particle | gap | | thickness |
| | | size | width | | of layer |
| | Material Type | (nm) | (ev) | solvent | (nm) |
| anode | ITO | / | / | / | 100 |
| hole injection layer | PEDOT:PSS | / | / | / | 30 |
| first hole transport | TFB | / | / | chlorobenzene | 20 |
| layer | | | | | |
| first light-emitting | Blue QDs:ZnSe | / | / | cyclohexane | 20 |
| layer | | | | | |
| second N-type | ZnO | 8 | 3.3 | toluene | 25 |
| sublayer | | | | | |
| first N-type | Zn_{0.9}Mg_{0.1}O | 3.5 | 3.9 | ethanol | 10 |
| sublayer | | | | | |
| P-type layer | PEDOT:PSS | / | / | / | 30 |
| second hole | TFB | / | / | chlorobenzene | 25 |
| transport layer | | | | | |
| second light- | Blue QDs:ZnSe | / | / | cyclohexane | 20 |
| emitting layer | | | | | |
| Electron transport | Zn_{0.95}Mg_{0.05}O | / | / | ethanol | 30 |
| layer | | | | | |
| cathode | Ag | / | / | / | 100 |

Accordingly, step (5) of the preparation method is as follows.

The second N-type sublayer material solution obtained in the step (1) was spin-coated on the first light-emitting layer to obtain a second N-type sublayer with a thickness of 25 nm. The first N-type sublayer material solution obtained in the step (1) was spin-coated on the second N-type sublayer to obtain a first N-type sublayer with a thickness of 10 nm. PEDOT:PSS was spin-coated on the first N-type sublayer to obtain a P-type layer having a thickness of 30 nm. A TFB chlorobenzene solution was spin-coated on the P-type layer to obtain a second hole transport layer having a thickness of 25 nm. The first N-type sublayer, the second N-type sublayer, the P-type layer, and the second hole transport layer together constitute a connecting layer.

### Comparative Example 4

Comparative Example 4 is basically the same as Example 9, except that the QLED device provided in Comparative Example 4 has only one N-type layer, and its specific structure and materials of each layer are shown in the following table:

TABLE 1-14

| | | Material Properties | | | |
|---|---|---|---|---|---|
| | | average | band | | |
| | | particle | gap | | thickness |
| | | size | width | | of layer |
| | Material Type | (nm) | (ev) | solvent | (nm) |
| anode | ITO | / | / | / | 100 |
| hole injection layer | PEDOT:PSS | / | / | / | 30 |
| first hole transport | TFB | / | / | chlorobenzene | 20 |
| layer | | | | | |
| first light-emitting | Blue QDs:ZnSe | / | / | cyclohexane | 20 |
| layer | | | | | |
| first N-type | Zn_{0.9}Mg_{0.1}O | 3.5 | 3.9 | ethanol | 35 |
| sublayer a | | | | | |
| P-type layer a | PEDOT:PSS | / | / | / | 30 |
| second hole | TFB | / | / | chlorobenzene | 25 |
| transport layer | | | | | |
| second light- | Blue QDs:ZnSe | / | / | cyclohexane | 20 |
| emitting layer | | | | | |
| first N-type | Zn_{0.9}Mg_{0.1}O | 3.5 | 3.9 | ethanol | 35 |
| sublayer b | | | | | |
| P-type layer b | PEDOT:PSS | / | / | / | 30 |
| third hole transport | TFB | / | / | chlorobenzene | 25 |
| layer | | | | | |
| third light-emitting | Blue QDs:ZnSe | / | / | cyclohexane | 20 |
| layer | | | | | |
| Electron transport | Zn_{0.95}Mg_{0.05}O | / | / | ethanol | 30 |
| layer | | | | | |
| cathode | Ag | / | / | / | 100 |

Accordingly, in the steps (5) and (6-1) of the method, the preparation steps of the second N-type sublayer a and the second N-type sublayer b were deleted, and the P-type layer a was directly prepared on the first N-type sublayer a, and the P-type layer b was prepared on the first N-type sublayer b. The thicknesses of the first N-type sublayer a and the first N-type sublayer b were made to be 35 nm.

### Comparative Example 5

Comparative Example 5 is basically the same as Example 10, except that the QLED device provided in Comparative Example 5 has only one N-type layer (without second N-type sublayer), and its specific structure and materials of each layer are shown in the following table:

TABLE 1-15

| | | Material Properties | | | |
|---|---|---|---|---|---|
| | | average | band | | |
| | | particle | gap | | thickness |
| | | size | width | | of layer |
| | Material Type | (nm) | (ev) | solvent | (nm) |
| anode | ITO | / | / | / | 100 |
| hole injection layer | PEDOT:PSS | / | / | / | 30 |
| first hole transport | TFB | / | / | chlorobenzene | 20 |
| layer | | | | | |
| first light-emitting | Red QDs:CdZnSe/ | / | / | cyclohexane | 20 |
| layer | ZnSe/ZnS | | | | |
| first N-type | Zn_{0.9}Mg_{0.1}O | 3.5 | 3.9 | ethanol | 10 |
| sublayer | | | | | |
| P-type layer | PEDOT:PSS | / | / | / | 30 |
| second hole | TFB | / | / | chlorobenzene | 25 |
| transport layer | | | | | |
| second light- | Red QDs:CdZnSe/ | / | / | cyclohexane | 20 |
| emitting layer | ZnSe/ZnS | | | | |
| Electron transport | Zn_{0.95}Mg_{0.05}O | / | / | ethanol | 30 |
| layer | | | | | |
| cathode | Ag | / | / | / | 100 |

Accordingly, step (5) of the preparation method is as follows.

The first N-type sublayer material solution obtained in the step (1) was spin-coated on the first light-emitting layer to obtain a first N-type sublayer with a thickness of 35 nm. PEDOT:PSS was spin-coated on the first N-type sublayer to obtain a P-type layer having a thickness of 30 nm. A TFB chlorobenzene solution was spin-coated on the P-type layer to obtain a second hole transport layer having a thickness of 25 nm. The first N-type sublayer, the P-type layer, and the second hole transport layer together constitute a connecting layer.

### Experimental Example

The devices prepared in the above Examples and Comparative Examples were tested for driving voltage and current efficiency. The test methods refer to conventional methods in the art, and the results are recorded in Table 2.

The testing method of current efficiency C.E is as follows: using Fostar FPD optical characteristic measurement equipment, controlling the efficiency testing system built by QE PRO spectrometer, Keithley 2400, and Keithley 6485 through LabView, measuring voltage, current, brightness, luminescence spectrum and other parameters, and calculating the current efficiency C.E.

The detection method of driving voltage @ J10 is as follows: the change trend of device current with voltage is tested by voltammetry, and the voltage at a current density of 10 mA/cm2 is obtained.

TABLE 2

| | driving voltage @J10 (V) | CE (cd/A) |
|---|---|---|
| Example 1 | 13.2 | 16.8 |
| Example 2 | 12.9 | 17.1 |
| Example 3 | 12.8 | 13 |
| Example 4 | 14.0 | 16.2 |
| Example 5 | 12.7 | 13.0 |
| Example 6 | 14.4 | 15.5 |
| Example 7 | 14.3 | 15.3 |
| Example 8 | 12.8 | 17.0 |
| Example 9 | 21.0 | 19.9 |
| Example 10 | 7.8 | 65 |
| Comparative Example 1 | 14.5 | 15 |
| Comparative Example 2 | 17.8 | 4.5 |
| Comparative Example 3 | 19.2 | 3 |
| Comparative Example 4 | 23.0 | 19.0 |
| Comparative Example 5 | 10.3 | 56 |

As can be seen from Table 2:

Examples 1 to 8 have lower driving voltages or higher current efficiency CE than Comparative Examples 1 to 3, Example 9 has lower driving voltages and higher current efficiency CE than Comparative Example 4, and Example 10 has lower driving voltages and higher current efficiency CE than Comparative Example 5, which illustrate that the light-emitting device proposed by the present disclosure can effectively reduce the driving voltage and improve photoelectric performance.

The technical solutions provided by the embodiments of the present disclosure have been described in detail above, and the principles and embodiments of the present disclosure have been described herein by applying specific examples, and the description of the above embodiments is only for helping to understand the methods and core ideas of the present disclosure. Meanwhile, those skilled in the field may change the specific embodiments and the scope of application according to the ideas of the present disclosure, and in summary, the contents of the present specification should not be construed as limiting the present disclosure.

What is claimed is:

1. A light-emitting device, comprising a first electrode, a second electrode disposed opposite the first electrode, n light-emitting layers disposed between the first electrode and the second electrode, and m connecting layers disposed between the first electrode and the second electrode, where n and m are positive integers;
wherein at least one of the connecting layers comprises an N-type layer, the N-type layer comprising a plurality of N-type sublayers, with a material of each of the N-type sublayers independently comprising an N-type metal oxide.

2. The light-emitting device according to claim 1, wherein at least one of the connecting layers is disposed between two adjacent light-emitting layers; and
the first electrode is selected from one of an anode and a cathode, and the second electrode is selected from the other of the anode and the cathode.

3. The light-emitting device according to claim 2, wherein the connecting layer is disposed between two adjacent light-emitting layers, and one connecting layer is disposed between any two adjacent light-emitting layers.

4. The light-emitting device according to claim 2, wherein the connecting layer further comprises a P-type layer stacked on a side of a plurality of N-type sublayers, and the N-type layer is disposed close to the anode and the P-type layer is disposed close to the cathode.

5. The light-emitting device according to claim 2, wherein in the N-type layer, an average particle size of the N-type metal oxide contained in the N-type sublayer closest to the cathode is larger than an average particle size of the N-type metal oxide contained in the N-type sublayer farthest from the cathode.

6. The light-emitting device according to claim 5, wherein the average particle size of the N-type metal oxide contained in the N-type sublayer gradually decreases in a direction from the cathode to the anode.

7. The light-emitting device according to claim 2, wherein in the N-type layer, a band gap width of the N-type metal oxide contained in the N-type sublayer closest to the cathode is smaller than a band gap width of the N-type metal oxide contained in the N-type sublayer farthest from the cathode.

8. The light-emitting device according to claim 7, wherein the band gap width of the N-type metal oxide contained in the N-type sublayer gradually increases in a direction from the cathode to the anode.

9. The light-emitting device according to claim 2, wherein in the N-type layer, a thickness of the N-type sub-layer closest to the cathode is greater than or equal to a thickness of the N-type sub-layer farthest from the cathode.

10. The light-emitting device according to claim 1, wherein at least one of the connecting layers is disposed between the first electrode and the light-emitting layer closest to the first electrode; and
at least one of the connecting layers is disposed between the second electrode and the light-emitting layer closest to the second electrode.

11. The light-emitting device according to claim 4, wherein the number of the light-emitting layers is 2 to 4, the number of the connecting layers is 1 to 3, and the number of the N-type sublayers in the N-type layer is 1 to 3;
the N-type layer has a thickness of 30 to 50 nm, the P-type layer has a thickness of 10 nm to 30 nm, and the N-type sublayer has a thickness of 10 nm to 40 nm.

12. The light-emitting device according to claim 4, wherein the N-type metal oxide has an average particle size of 1 nm to 20 nm;
the N-type metal oxide comprises one or more of an undoped metal oxide and a doped metal oxide, the undoped metal oxide comprises one or more of ZnO, TiO₂, and SnO₂; a metal oxide in the doped metal oxide comprises one or more of ZnO, TiO₂, and SnO₂, and a doping element in the doped metal oxide comprises one or more of Al, Mg, Li, In, and Ga; and
a material of the P-type layer comprises at least one of polythiophene, polyaniline, 2,3,6,7,10,11-hexacyano-1,4,5,8,9,12-hexaazabenzophenanthrene, PEDOT, PEDOT:PSS, a derivative of PEDOT:PSS doped with s-MoO₃, 4,4′,4′-tris(N-3-methylphenyl-N-phenylamino) triphenylamine, tetracyanoquinone dimethane, copper phthalocyanine, nickel oxide, molybdenum oxide, tungsten oxide, vanadium oxide, molybdenum sulfide, tungsten sulfide and copper oxide.

13. The light-emitting device according to claim 4, wherein the plurality of light-emitting layers comprise a first light-emitting layer and a second light-emitting layer, the N-type layer comprises a first N-type sublayer and a second N-type sublayer, and the light-emitting device comprises the first electrode, the first light-emitting layer, the connecting layer, the second light-emitting layer, and the second electrode that are stacked in this order, and the connection layer comprises the first N-type sublayer, the second N-type sublayer, and the P-type layer that are stacked in this order in a direction of the first electrode toward the second electrode.

14. The light-emitting device according to claim 13, wherein a material of the first N-type sublayer and a material of the second N-type sublayer are each independently selected from one or more of doped zinc oxide nanoparticles, undoped zinc oxide nanoparticles, doped tin oxide nanoparticles and undoped tin oxide nanoparticles.

15. The light-emitting device according to claim 14, wherein the material of the first N-type sublayer has an average particle size of 2 nm to 5 nm;
a band gap width of the material of the first N-type sublayer is 3.6 nm to 4.2 ev;
a thickness of the first N-type sublayer is 10 nm to 20 nm;
the material of the second N-type sublayer has an average particle size of 5 nm to 8 nm;
a band gap width of the material of the second N-type sublayer is 3.2 nm to 3.6 ev; and
a thickness of the second N-type sublayer is 20 nm to 40 nm.

16. The light-emitting device according to claim 1, wherein the first electrode and the second electrode are each independently selected from one of a metal electrode, a carbon electrode, a doped or undoped metal oxide electrode, and a composite electrode; wherein a material of the metal electrode is selected from at least one of Al, Ag, Cu, Mo, Au, Ba, Ca, Ni, Ir, and Mg; a material of the carbon electrode is selected from at least one of graphite, carbon nanotubes, graphene, and carbon fibers; a material of the doped or undoped metal oxide electrode is selected from at least one of ITO, FTO, ATO, AZO, GZO, IZO, MZO, ITZO, ICO, AMO, SnO₂, In₂O₃, Cd:ZnO, and Ga:SnO₂; a material of the composite electrode is selected from one of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS and ZnS/Al/ZnS; and
each time the light-emitting layer appears, a material of the light-emitting layer is independently selected from quantum dot light-emitting materials; the quantum dot light-emitting materials are selected from at least one of the group consisting of a single structure quantum dot, a core-shell structure quantum dot, and a perovskite type semiconductor material, the core-shell structure quantum dot has one or more shell layers; a material of the single structure quantum dot is selected from at least one of a Group II-VI compound, a Group IV-VI compound, a Group III-V compound, and a Group I-III-VI compound; the Group II-VI compound is selected from at least one of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe; the Group IV-VI compound is selected from at least one of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe; the Group III-V compound is selected from at least one of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb; the Group I-III-VI compound is selected from one or more of CuInS, CuInSe, and AgInS; a core of the core-shell structure quantum dot is selected from any one of the single structure quantum dots, and a shell material of the core-shell structure quantum dot is selected from at least one of CdS, CdTe, CdSeTe, CdZnSe, CdZnS, CdSeS, ZnSe, ZnSeS, and ZnS; the perovskite type semiconductor is selected from one of a doped inorganic perovskite type semiconductor, an undoped inorganic perovskite type semiconductor, and an organic-inorganic hybrid perovskite type semiconductor, a general structure formula of the inorganic perovskite type semiconductor is AMX₃, wherein A is Cs⁺, M is a divalent metal cation selected from one of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, X is a halogen anion selected from one of Cl⁻, Br⁻, and I⁻; a general structure formula of the organic-inorganic hybrid perovskite type semiconductor is BMX₃, wherein B is an organic amine cation selected from CH₃(CH₂)ₙ₋₂NH₃⁺ (n≥2) or NH₃(CH₂)ₙNH₃²⁺ (n≥2), M is a divalent metal cation selected from one of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, X is a halogen anion selected from one of Cl⁻, Br⁻, and I⁻.

17. A method of preparing a light-emitting device, comprising:
providing a first electrode;
providing a light-emitting functional layer on a side of the first electrode, wherein the light-emitting functional layer comprises n light-emitting layers and m connecting layers, where n and m are positive integers; and,
providing a second electrode on a side of the light-emitting functional layer facing away from the first electrode to obtain a light-emitting device;
wherein the first electrode is selected from one of an anode and a cathode, and the second electrode is selected from the other of the anode and the cathode;
the process of preparing the N-type layer comprises providing a plurality of solutions, each containing an N-type metal oxide, and sequentially depositing a plurality of the solutions to obtain a plurality of N-type sublayers.

18. The method according to claim 17, wherein the connecting layer further comprises a P-type layer stacked on a side of a plurality of N-type sublayers, and the N-type layer is disposed close to the anode and the P-type layer is disposed close to the cathode;
in the N-type layer, an average particle size of the N-type metal oxide contained in the N-type sublayer closest to the cathode is larger than an average particle size of the N-type metal oxide contained in the N-type sublayer farthest from the cathode;
in the N-type layer, a band gap width of the N-type metal oxide contained in the N-type sublayer closest to the cathode is smaller than a band gap width of the N-type metal oxide contained in the N-type sublayer farthest from the cathode; and
solvents in the solutions corresponding to two adjacent N-type sublayers are orthogonal.

19. The method according to claim 18, wherein the preparation of the light-emitting functional layer comprises:
providing a first solution containing a first light-emitting layer material, depositing the first solution on a side of the first electrode to obtain a first light-emitting layer;
providing a second solution containing a first N-type metal oxide, depositing the second solution on a side of the first light-emitting layer facing away from the first electrode to obtain a first N-type sublayer;
providing a third solution containing a second N-type metal oxide, depositing the third solution on a side of the first N-type sublayer facing away from the first light-emitting layer to obtain a second N-type sublayer;
providing a fourth solution containing a P-type layer material, depositing the fourth solution on a side of the second N-type sublayer facing away from the first N-type sublayer to obtain a P-type layer;
providing a fifth solution containing a second light-emitting layer material, depositing the fifth solution on a side of the P-type layer facing away from the second N-type sublayer to obtain a second light-emitting layer;
wherein an average particle size of the first N-type metal oxide is smaller than an average particle size of the second N-type metal oxide; an average particle size of the first N-type metal oxide is 2 nm to 5 nm; an average particle size of the second N-type metal oxide is 5 nm to 8 nm;
a band gap width of the first N-type metal oxide is greater than a band gap width of the second N-type metal oxide; the band gap width of the first N-type metal oxide is 3.6 ev to 4.2 ev; the second N-type metal oxide has a band gap width of 3.2 ev to 3.6 ev;
the first light-emitting layer material and the second light-emitting layer material are each independently selected from quantum dot light-emitting materials;
the P-type layer material comprises at least one of polythiophene, polyaniline, 2,3,6,7,10,11-hexacyano-1,4,5,8,9,12-hexaazabenzophenanthrene, PEDOT, PEDOT:PSS, a derivative of PEDOT:PSS doped with s-MoO₃, 4,4′,4′-tris(N-3-methylphenyl-N-phenylamino) triphenylamine, tetracyanoquinone dimethane, copper phthalocyanine, nickel oxide, molybdenum oxide, tungsten oxide, vanadium oxide, molybdenum sulfide, tungsten sulfide and copper oxide;
the second solution further comprises a first polar solvent comprising one or more of methanol, ethanol, isopropanol, 2-methoxyethanol, benzyl alcohol, and cyclopentanol;
the third solution further comprises a non-polar solvent comprising one or more of cyclopentanone, toluene, cyclohexylbenzene, chlorobenzene, and octadecane; and
the fourth solution comprises a second polar solvent comprising one or more of methanol, ethanol, isopropanol, 2-methoxyethanol, benzyl alcohol, and cyclopentanol.

20. A display device comprising a light-emitting device, wherein the light-emitting device comprises a first electrode, a second electrode disposed opposite the first electrode, n light-emitting layers disposed between the first electrode and the second electrode, and m connecting layers disposed between the first electrode and the second electrode, where n and m are positive integers;
wherein at least one of the connecting layers comprises an N-type layer, the N-type layer comprising a plurality of N-type sublayers, with a material of each of the N-type sublayers independently comprising an N-type metal oxide.
